(19) United States
(12) Patent Application Publication
(10) Pub. No.: US 2011/0134588 A1
(43) Pub. Date: Jun. 9, 2011

(54) PORTABLE APPARATUS

(75) Inventor: Ricky William BARNETT, Hertfordshire (GB)

(73) Assignee: Nokia Corporation

(21) Appl. No.: 12/630,006

(22) Filed: Dec. 3, 2009

(51) Int. Cl. H05K 5/00; F16M 13/00

(52) U.S. Cl. 361/679.01; 248/354.1

(57) ABSTRACT

An electronic apparatus including a body having a first face and an opposing second face, wherein the first face includes a user interface; and a supporting mechanism configured to support the body on a surface such that the user interface is presented at an incline to the surface, wherein the supporting mechanism is associated with the second face and includes a first arm having a first end mounted at a first pivot that is positioned at the body and having a second end mounted at a second pivot; a second arm having a first end mounted at the second pivot and having a second end; and a driver configured to control the rotation of the second pivot about the first pivot.

### FIELD OF THE INVENTION

Embodiments of the present invention relate to portable apparatus. In particular, portable apparatus with user interface.

### BACKGROUND TO THE INVENTION

Some portable apparatus have user interfaces that are designed to present information to a user over an extended time period. The information may, for example, be video content. It is, of course, desirable to have the user interface presented to the user with an orientation relative to the user that allows the user to use the user interface in comfort over the extended time period.

### BRIEF DESCRIPTION OF VARIOUS EMBODIMENTS OF THE INVENTION

According to various, but not necessarily all, embodiments of the invention there is provided a portable apparatus comprising: a body having a first face and an opposing second face, wherein the first face comprises a user interface; and a supporting mechanism configured to support the body on a surface such that the user interface is presented at an incline to the surface, wherein the supporting mechanism is associated with the second face and comprises: a first arm having a first end mounted at a first pivot that is positioned at the body and having a second end mounted at a second pivot; a second arm having a first end mounted at the second pivot and having a second end; and a driver configured to control the rotation of the second pivot about the first pivot.

According to various, but not necessarily all, embodiments of the invention there is provided a method of supporting an electronic apparatus comprising: enabling the relative rotational movement between: a first arm having a first end mounted at a first pivot that is positioned at a body of the apparatus and having a second end mounted at a second pivot; and a second arm having a first end mounted at the second pivot and having a second end for abutting the surface; and driving the relative rotational movement between the first arm and the second arm.

### BRIEF DESCRIPTION OF THE DRAWINGS

For a better understanding of various examples of embodiments of the present invention reference will now be made by way of example only to the accompanying drawings in which:

FIGS. 1A to 1D schematically illustrate a first embodiment in which a portable apparatus comprises a supporting mechanism that has an extendible/contractible foldable strut;

FIGS. 2A to 2D schematically illustrate a second embodiment in which a portable apparatus comprises a supporting mechanism that has an extendible/contractible foldable strut;

FIGS. 3A to 3C schematically illustrate the second embodiment from a rear perspective; and

FIGS. 4A and 4B schematically illustrate different examples of user interfaces.

### DETAILED DESCRIPTION OF VARIOUS EMBODIMENTS OF THE INVENTION

The Figs schematically illustrate a portable apparatus 1 comprising: a body 2 having a first face 3 and an opposing second face 4, wherein the first face 3 comprises a user interface 7. The apparatus 1 also comprises a supporting mechanism 10 configured to support the body on a surface such that the user interface is presented at an incline to the surface. The supporting mechanism 10 is associated with the second face 4 and comprises: a first arm 12 having a first end 13 mounted at a first pivot 11 that is positioned at the body 2 and having a second end 14 mounted at a second pivot 21; a second arm 22 having a first end 23 mounted at the second pivot 21 and having a second end 24; and at least one driver 16 configured to control the rotation of the second pivot 21 about the first pivot 11.

The apparatus may be a hand portable apparatus. Hand-portable means that it is a portable apparatus that is sized to be carried in a palm of the hand. It will typically be sized to fit into a pocket of a suit or a handbag. The apparatus may, for example, be a communications device and/or a personal music device and/or a video display device and/or a navigation device and/or a gaming device.

The apparatus may be an electronic apparatus. It may have different functionality. It may, for example, operate as a video player or other apparatus that display video content such as a video telephone. It may also have additional functionality. It may for example also operate as a personal music player and/or a cellular telephone and/or an internet access device for example.

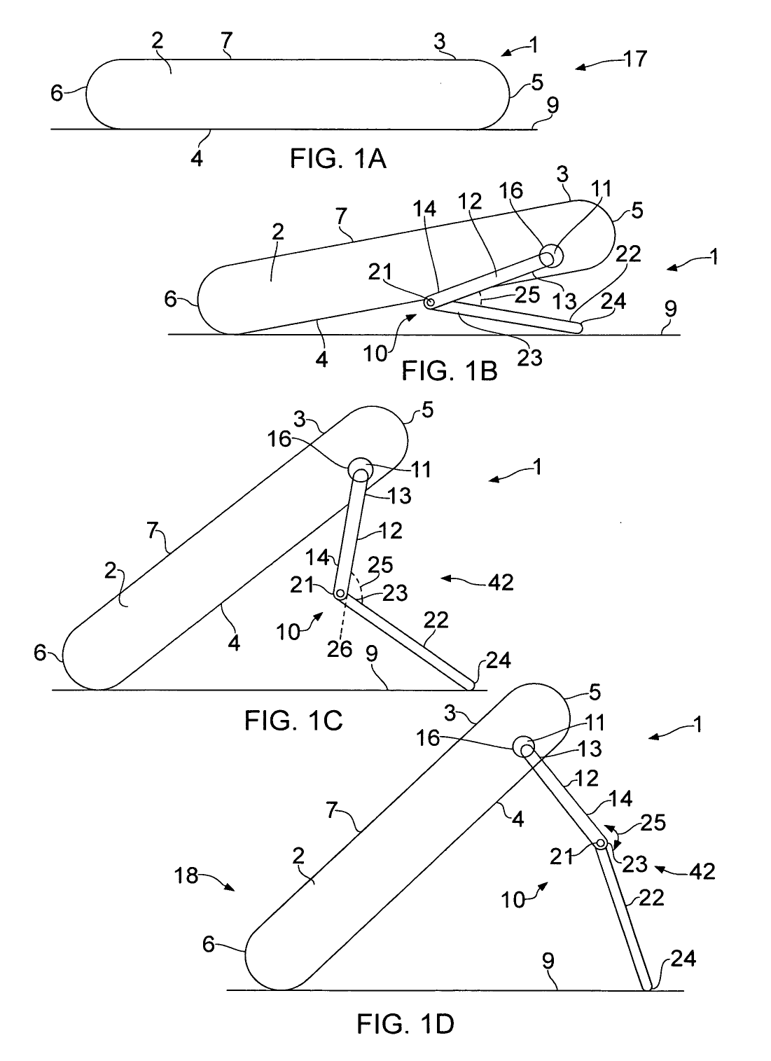

FIGS. 1A to 1D schematically illustrate a first embodiment in which a hand portable electronic apparatus 1 comprises a supporting mechanism 10 that has an extendible/contractible foldable strut 42. The strut 42 is configured to rotate about a first pivot 11 when it extends/contracts. The strut 42 is formed from a first arm 12 and a second arm 22 that are interconnected via a second pivot 21.

In a compact configuration 17 such as that illustrated in FIG. 1A, the strut 42 is folded over on itself within or against a body 2 of the hand portable apparatus 1.

In FIG. 1, a rear face 4 of the body 2 is resting on a flat surface 9. A front face 3 of the body 2 that is on the opposing side of the body 2 to the rear face 4 comprises a user interface 7. The user interface 7 is oriented so that it is substantially parallel to the flat surface 9 which is an inconvenient viewing angle for a user.

In an expanded configuration as illustrated in FIG. 1C and/or 1D, the strut 42 is extended and supports the body 2 at a pitched orientation in which a top end 5 of the body is raised relative to an opposing bottom end 6 by the supporting mechanism 10. In this pitched orientation, the front face 3 of the body is inclined relative to the flat surface 9. At this pitched orientation, the user interface 7 is oriented so that it is presented to a user at a convenient viewing angle relative to the flat surface 9.

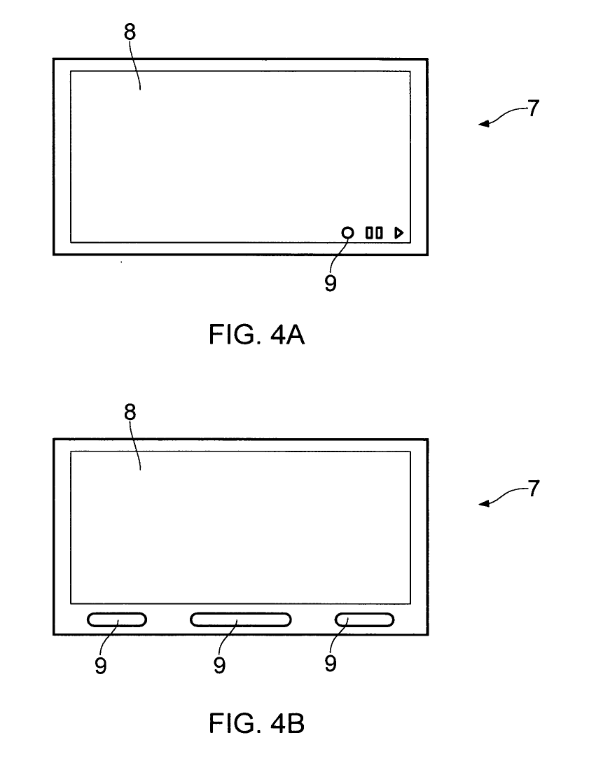

Some examples of user interfaces 7 are schematically illustrated in FIGS. 4A and 4B. In FIG. 4A, the user interface 7 comprises a display 8. Optionally, the display 8 may be a touch sensitive display which provides software keys 9 as part of the display. In FIG. 4B, the user interface 7 comprises a display 8. Optionally, the user interface 7 may additionally comprise hardware keys 9 that are separate to the display.

When extended, the strut 42 orientates the display 8 at a convenient viewing angle. If keys 9 are provided in the user interface 7 then it may be advantageous for the strut 42 to be rigid enough to prevent movement or collapse when the keys 9 are actuated however a simple rigid strut will break if the apparatus receives a downward impact or pressure. It is therefore advantageous to have the strut 42 designed so that it is resilient and will not break if the apparatus 1 receives a downward impact or pressure when the strut 42 is extended.

The supporting mechanism 10 in this example is associated with the rear face 4 in that it extends out from the rear face 4 from a folded/retracted position.

The supporting mechanism 10 comprises a first arm 12 and a second arm.

The first arm 12 is rigid or semi-rigid and extends between a first end 13 and a second end 14. The first end 13 of the first arm 12 is mounted at a first pivot 11. The second end 14 of the first arm 12 is mounted at a second pivot 21.

The first pivot 11 is also connected to the body 2. It is positioned towards the top end 5 and the rear face 4 of the hand portable apparatus 1.

In the FIGS. 1A to 1D, the first arm 12 rotates about the first pivot 11 in a counterclockwise direction relative to the body 2 when the strut 42 is extending and in a clockwise direction when the strut 42 is retracting.

The second pivot 21 is also connected to a first end 23 of the second arm 22.

The second arm 22 is rigid or semi-rigid and extends between the first end 23 and a second end 24, which acts as a foot of the strut 42.

In the FIGS. 1A to 1D, the second arm 22 rotates about its foot 24 in a clockwise direction relative to the flat surface 9 when the strut 42 is extending and in a counterclockwise direction when the strut 42 is retracting.

In the FIGS. 1A to 1D, the first arm 22 rotates about the second pivot 21 relative to the second arm 22 in a counterclockwise direction in the Figs when the strut 42 is extending and in a clockwise direction when the strut 42 is retracting. Whereas the second arm 22 rotates about the second pivot 21 relative to the first arm 12 in a clockwise direction in the Figs when the strut 42 is extending and in a counterclockwise direction when the strut 42 is retracting. Thus when the strut 42 is extending the first arm 12 and the second arm 22 are rotated about the second pivot 21 so that a greater angular separation is the result and when the strut 42 is retracting the first arm 12 and the second arm 22 are rotated about the second pivot 21 so that a smaller angular separation is the result.

In the compact configuration 17 illustrated in FIG. 1A, the first arm 12 and the second arm 22 form an acute angle 25 at the second pivot 21. The first arm 12 and second arm 22 are folded over on themselves underneath the body 2 such that the first end 13 of the first arm 12 and second end 24 of second arm 22 are in close proximity and the first arm 12 and second arm 22 are substantially parallel. The acute angle 25 may be zero or close to zero.

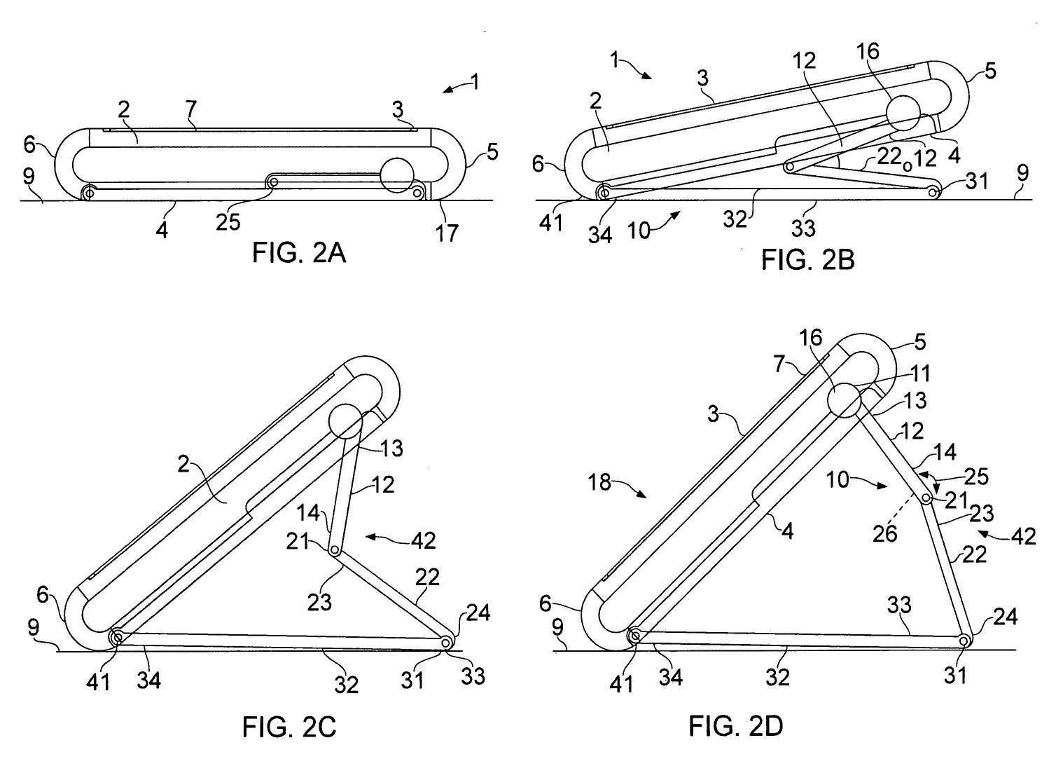

In the expanded configuration 18, the first arm 12 and the second arm 22 form an obtuse angle 25 (FIG. 2C) or a reflex angle (FIG. 2D) at the second pivot 21. The expanded configuration is a stable position that can be maintained.

In this embodiment, the foot 24 of the second arm 22 restrains movement of the second end of the second arm 22 along the flat surface 9. The foot 24 may in some embodiments be configured to prevent slipping and increase friction.

In some embodiments, the supporting mechanism 10 is comprises one or more drivers that is used to control the operation of the supporting mechanism 10. A driver may be designed to drive the strut 42 to its extended position and/or to drive the strut 42 to its retracted position. A driver may be designed to drive the strut 42 towards an equilibrium position when it is extended so that it is stable.

One example of a driver that is designed to drive the strut 42 to its extended position and to drive the strut 42 to its retracted position is a motor 16. The motor 16 may be any suitable motor. The motor 16 is positioned to drive the rotation of one of the first arm 12 or second arm 22 about the first pivot 11 or the second pivot 21. The most convenient location for the motor is within the body 2 in association with the first pivot 11. The motor drives the first arm counterclockwise to lift the body and clockwise to lower the body 2. The motor 16 may be actuated by any suitable switch. The switch may, for example, be provided through the user interface 7 as a hardware or software switch or by any other suitable technology.

Such a motor 16 may also be designed to drive the strut 42 towards an equilibrium position when it is extended so that it is stable. For example, when the strut 42 is extended, the motor 16 may ‘lock’ the strut into position via any suitable mechanism. The maintenance of a locked position may or may not require energizing the motor depending on implementation. When the strut 42 is ‘locked’ in the illustrated example the first arm 12 is held at a defined orientation relative to the body 2. A certain amount of deflection from this defined orientation may be accommodated for example if the body receives a downward impulse or pressure but the first arm 12 will return to its defined orientation after the deflection.

Another example of a driver that is designed to drive the strut 42 to its extended position is a biasing mechanism 16. The biasing mechanism may be any suitable mechanism that stores energy and releases the energy to rotate the first arm 12 about the first pivot 11. The energy may, for example, be stored mechanically in a spring.

The biasing mechanism 16 may be positioned to drive the rotation of one of the first arm 12 or second arm 22 about the first pivot 11 or the second pivot 21. One location for the biasing mechanism 16 is within the body 2 in association with the first pivot 11. The biasing mechanism 16 drives the first arm counterclockwise to lift the body 2.

When the strut 42 is retracted, the biasing mechanism is primed. For example, a spring may be under compression or tension depending upon design. Typically some form of latch will hold the strut 42 in the retracted position. When the latch is released, the energy released by the primed biasing mechanism 16 rotates the first arm 12 about the first pivot 11 and extends the strut 42. To retract the strut 42 typically requires a user to fold the strut 42 away. This action may automatically prime the biasing mechanism 16 for re-use and actuate the latch. The strut 42 is then ready to be extended again by releasing the latch.

Biasing mechanisms 26 may also optionally be used to bias or drive the strut 42 towards an equilibrium position when it is extended so that it is stable. For example, a biasing mechanism may be associated with the first pivot 11 or the second pivot 21 that defines preferred orientation of the first arm 12 or second arm 22 relative to that pivot and encourages the movement of the arm towards that defined orientation when it is deflected from that orientation. Such biasing mechanisms may for example be achieved in various ways including abutting a rotating eccentric cam against a camming surface or by using biasing springs.

In the FIGS. 1A to 1D, as the strut 42 is unfolded, the first arm 12 is rotated about the first pivot 11 in a counterclockwise direction and the angle the first arm 12 makes with a plane passing through both the top end 5 and bottom end 6 parallel to the front face 3, increases from close to zero to the defined orientation which may, for example, be any angle between 75 and 105 degrees or 80 and 100 degrees or 85 and 95 degrees.

The strut 42 is resilient in that it comprises an intermediate pivot 21 which allows relative rotational movement between the first arm 12 and the second arm 22. Thus if the body 2 received a downward impulse or pressure when in the extended configuration, the strut 42 resiliently deforms by, for example, rotation of the first arm 12 relative to the second arm 22 about the second pivot 21.

In FIGS. 1A to 1D, the first arm 12 and second arm 22 are substantially the same length. This is a design choice and they may have different lengths.

In the FIGS. 2A to 2D a second embodiment is illustrated in which a third arm 32 is used to restrain movement of the foot 24 of the strut 42.

In this embodiment, the supporting mechanism 10 further comprises a third arm 32.

The third arm 32 is rigid or semi-rigid and extends between a first end 33 and a second end 34.

The second end 34 of the third arm 32 is mounted at a fourth pivot 41. The fourth pivot 41 is positioned towards the bottom end 6 and the back face 4 of the apparatus 1.

In FIGS. 2A to 2D, the third arm 32 rotates about the fourth pivot 41 in a clockwise direction when the strut 42 is extending and in a counterclockwise direction when the strut 42 is retracting

The first end 33 of the third arm 32 is mounted at a third pivot 31 to which the second end 24 of the second arm 22 is also mounted.

In FIGS. 2A to 2D, the second arm 22 rotates about the third pivot 31 relative to the third arm 32 in a clockwise direction when the strut 42 is extending and in a counterclockwise direction when the strut 42 is retracting. Whereas, the third arm 32 rotates about the third pivot 31 relative to the second arm 22 in a counterclockwise direction when the strut 42 is extending and in a clockwise direction when the strut 42 is retracting. Thus when the strut 42 is extending the third arm 22 and the second arm 22 are rotated relative to each other about the second pivot 21 so that a greater angular separation is the result and when the strut 42 is retracting the third arm 32 and the second arm 22 are rotated relative to each other about the third pivot 31 so that a smaller angular separation is the result

The supporting mechanism 10 therefore comprises three links (arms) that are serially interconnected via two pivots. When the strut 42 is extending the second arm 22 rotates, in the FIGS. 2A to 2D, in a clockwise direction relative to the first arm 12 about the second pivot and relative to the third arm 32 about the third pivot 31.

In use the third arm 32 forms a base restraining movement of the foot 24 of the strut 42. The strut 42 is resilient in that it comprises an intermediate pivot 21 which allows relative rotational movement between the first arm 12 and the second arm 22. Thus if the body 2 received a downward impulse or pressure when in the extended configuration, the strut 42 would resiliently deform by, for example, rotation of the first arm 12 relative to the second arm 22 about the second pivot 21.

At least a portion of the third arm 32 may be configured to contact the surface 9 when the supporting mechanism is in an expanded configuration. This portion of the third arm 32 may comprise a high friction coating that is positioned to contact the surface when the supporting mechanism is in an expanded configuration. The high friction coating may prevent slipping and may, for example, be formed from rubber, a polymer or other suitable material.

Drivers as described with reference to FIGS. 1A to 1C may also be used with this embodiment. However, it should be appreciated that as there are two additional pivots 31, 41, there are two additional locations for drivers.

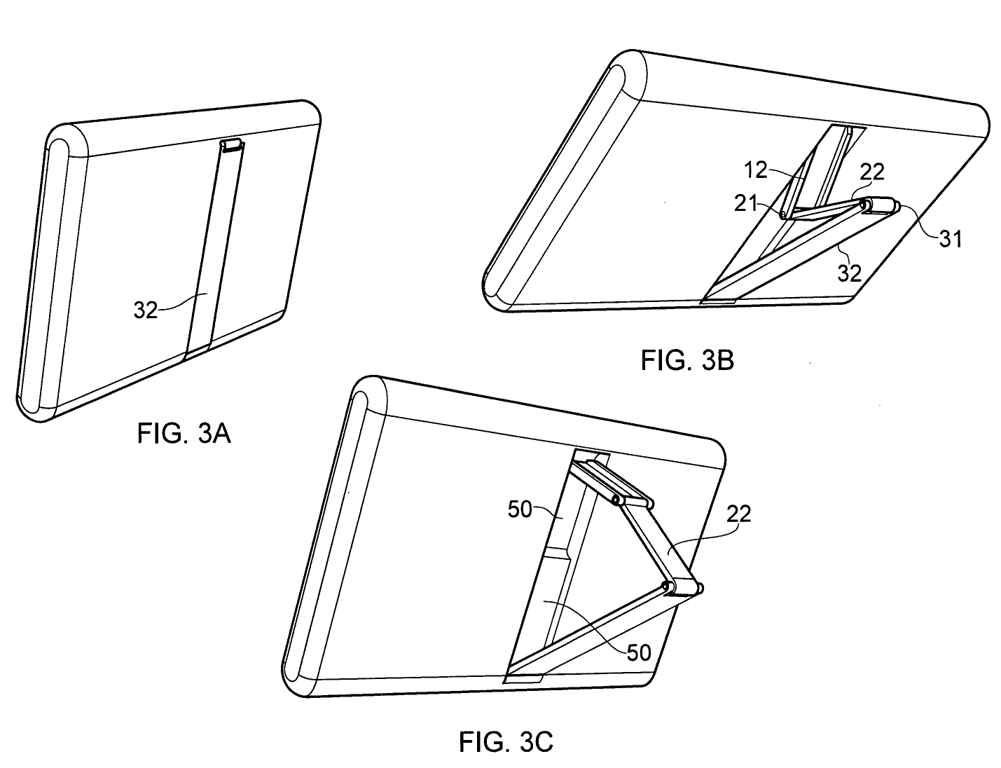

FIGS. 3A to 3C schematically illustrate how the supporting mechanism 10 may be stowed into a recess 50 in the back face 4 of the body. FIG. 3A corresponds to the arrangement illustrated in FIG. 2A but from a different perspective. FIG. 3B corresponds to the arrangement illustrated in FIG. 2B but from a different perspective. FIG. 3C corresponds to the arrangement illustrated in FIG. 2C but from a different perspective. It will be appreciated that the recess has two connected parts. The first arm 12 and second arm 22 are folded into a first part of the cavity 50. The third arm 32 folds over the folded first and second arms into the first part of the cavity 50 and also into an adjacent and interconnected second shallower part of the cavity 50. The depths of the parts of the cavity 50 may be controlled to determine whether the supporting mechanism 10 when retracted is slightly below the back face 4, slightly above the back face 4 or flush to the back face 4.

Although embodiments of the present invention have been described in the preceding paragraphs with reference to various examples, it should be appreciated that modifications to the examples given can be made without departing from the scope of the invention as claimed. For example, a high friction coating may be applied to arms where they will contact the surface 9 when the supporting mechanism is in an expanded configuration. The high friction coating may prevent slipping and may, for example, be formed from rubber, a polymer or other suitable material.

Features described in the preceding description may be used in combinations other than the combinations explicitly described.

The terms ‘clockwise’ and ‘anticlockwise’ are understandable in the context of views provided by the drawings. Rotation about a pivot, can be defined using polar coordinates rθ, where r extends along an arm from the pivot and θ is positive (0≦θ≦N. 2π, N>1). Counterclockwise rotation implies an increasing θ. Clockwise rotation implies a decreasing θ. It should be appreciated that whether rotation appears clockwise or counterclockwise depends upon which side of the pivot the rotation is viewed from.

Although functions have been described with reference to certain features, those functions may be performable by other features whether described or not.

Although features have been described with reference to certain embodiments, those features may also be present in other embodiments whether described or not.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

I/We claim:

1. A portable apparatus comprising:
a body having a first face and an opposing second face, wherein the first face comprises a user interface; and
a supporting mechanism configured to support the body on a surface such that the user interface is presented at an incline to the surface,
wherein the supporting mechanism is associated with the second face and comprises:
a first arm having a first end mounted at a first pivot that is positioned at the body and having a second end mounted at a second pivot;
a second arm having a first end mounted at the second pivot and having a second end; and
a driver configured to control the rotation of the second pivot about the first pivot.

2. A portable apparatus as claimed in claim 1, wherein the first pivot is positioned towards a top end and the second face of the apparatus and is associated with the driver.

3. A portable apparatus as claimed in claim 1, wherein the driver is a motor.

4. A portable apparatus as claimed in claim 1, wherein the user interface comprises a display and at least one key that is active when the display is in use.

5. A portable apparatus as claimed in claim 1, wherein the first arm and second arm are configured to rotate during an expansion of the supporting mechanism to an expanded configuration, in opposite senses about the second pivot.

6. A portable apparatus as claimed in claim 1, having a compact configuration in which the first arm and the second arm form an acute angle at the second pivot and an expanded configuration in which the first arm and the second arm form an obtuse or reflex angle at the second pivot.

7. A portable apparatus as claimed in claim 1, comprising a restraint for restricting movement of the second end of the second arm.

8. A portable apparatus as claimed in claim 1, wherein the supporting mechanism further comprises:
a third arm having a first end mounted at a third pivot and a second end that is mounted at a fourth pivot that is positioned at the body;
wherein the second end of the second arm is also mounted at the third pivot.

9. A portable apparatus as claimed in claim 8, wherein the third arm and second arm are configured to rotate during an expansion of the supporting mechanism to an expanded configuration, in opposite senses about the third pivot.

10. A portable apparatus as claimed in claim 8, wherein a driver is or drivers are associated with one or more of the first pivot, the second pivot, the third pivot and the fourth pivot.

11. A portable apparatus as claimed in claim 10, wherein at least one driver is a motor.

12. A portable apparatus as claimed in claim 10, wherein at least one driver is a biasing mechanism.

13. A portable apparatus as claimed in claim 8, wherein at least a portion of the third arm is configured to contact the surface when the supporting mechanism is in an expanded configuration, and wherein at least the portion of the third arm comprises a high friction coating that is positioned to contact the surface when the supporting mechanism is in an expanded configuration.

14. A portable apparatus as claimed in claim 1, wherein the supporting mechanism provides a resilient extendible/retractable foldable strut.

15. A portable apparatus as claimed in claim 14, further comprising a third arm configured to restrain movement of a foot of the strut when extended.

16. A portable apparatus as claimed in claim 15 comprising a recess in the second face for receiving the strut when retracted and folded.

17. A method of supporting an electronic apparatus comprising:
enabling the relative rotational movement between:
a first arm having a first end mounted at a first pivot that is positioned at a body of the apparatus and having a second end mounted at a second pivot; and
a second arm having a first end mounted at the second pivot and having a second end for abutting the surface; and
driving the relative rotational movement between the first arm and the second arm.

18. A method as claimed in claim 17 further comprising enabling rotation of the first arm and second arm in opposite senses about the second pivot.

19. A method as claimed in claim 18 further comprising enabling rotation of the second arm and a third arm in opposite senses about a third pivot, and also enabling rotation of the third arm about a fourth pivot at the body of the apparatus.
